(19) United States
(12) Patent Application Publication
(10) Pub. No.: US 2016/0021768 A1
(43) Pub. Date: Jan. 21, 2016

(54) Multi-Purpose Enclosures And Methods For Removing Heat In The Enclosures

(71) Applicant: Emerson Network Power, Energy Systems, North America, Inc., Warrenville, IL (US)

(72) Inventor: James William WEBSTER, Addison, IL (US)

(21) Appl. No.: 14/336,920

(22) Filed: Jul. 21, 2014

(51) Int. Cl. H05K 5/02

(52) U.S. Cl. CPC H05K 5/0213

(57) ABSTRACT

A multi-purpose enclosure for telecommunication applications includes plural walls defining a first chamber and a second chamber, and a heat generating component positioned in the first chamber. At least one of the plural walls separates the first chamber and the second chamber. At least a portion of the wall separating the first chamber and the second chamber spans an area defined by a width and a height. The wall portion has a surface area that is greater than a product of the width and the height. The plural walls define an airflow path adjacent to the wall portion for removing from the enclosure heat generated by the heat generating component and thermally conducted from the first chamber to the second chamber through the wall portion. Other example enclosures are also disclosed.

### FIELD

The present disclosure relates to multi-purpose enclosures and methods for removing heat in the enclosures.

### BACKGROUND

This section provides background information related to the present disclosure which is not necessarily prior art.

Enclosures for housing heat generating components commonly include heat exchangers to remove heat from the enclosures. The heat exchangers may include passive heat exchangers such as heat sinks, vents, etc. and/or other types of heat exchangers such as fans.

### SUMMARY

This section provides a general summary of the disclosure, and is not a comprehensive disclosure of its full scope or all of its features.

According to one aspect of the present disclosure, a multi-purpose enclosure for telecommunication applications is disclosed. The enclosure includes plural walls defining a first chamber and a second chamber, and a heat generating component positioned in the first chamber. At least one of the plural walls separates the first chamber and the second chamber. At least a portion of the wall separating the first chamber and the second chamber spans an area defined by a width and a height. The wall portion has a surface area that is greater than a product of said width and said height. The plural walls define an airflow path adjacent to the wall portion for removing from the enclosure heat generated by the heat generating component and thermally conducted from the first chamber to the second chamber through the wall portion.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a block diagram of a multi-purpose enclosure including two chambers separated by a wall having a corrugated configuration according to one example embodiment of the present disclosure.

FIG. 2 is a sectional view taken along line 2-2 in FIG. 1.

FIG. 3A is a corrugated configuration according to another example embodiment.

FIG. 3B is a corrugated configuration according to yet another example embodiment.

FIG. 4 is a block diagram of a multi-purpose enclosure including one chamber positioned in another chamber and having a wall including a corrugated configuration according to another example embodiment.

FIG. 5 is a block diagram of one heat sink for thermally coupling to four heat generating components according to yet another example embodiment.

FIG. 6 is a block diagram of a multi-purpose enclosure including two chambers, a heat generating component positioned in one of the chambers, and a fan coupled to the heat generating component according to another example embodiment.

FIG. 7 is a block diagram of a multi-purpose enclosure including vents and a fan according to yet another example embodiment.

FIG. 8 is a block diagram of a multi-purpose enclosure including walls having different reflection coefficients according to another example embodiment.

Corresponding reference numerals indicate corresponding parts or features throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

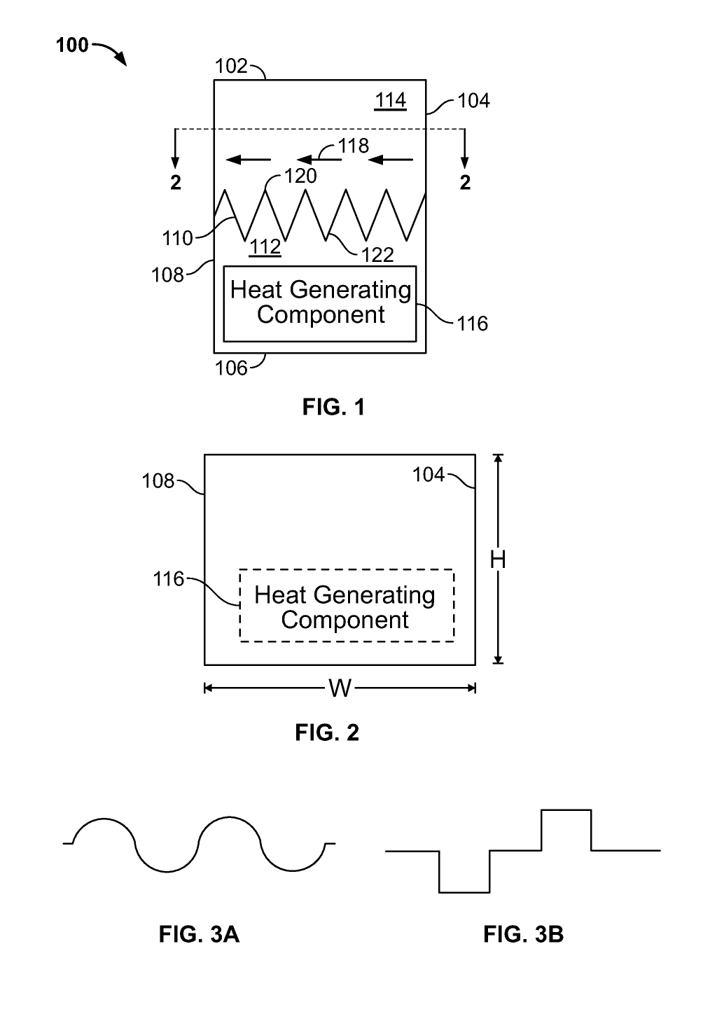

A multi-purpose enclosure for telecommunication applications according to one example embodiment of the present disclosure is illustrated in FIGS. 1 and 2, and indicated generally by reference number 100. As shown in FIGS. 1 and 2, the multi-purpose enclosure 100 includes plural walls 102, 104, 106, 108, 110 defining a chamber 112 and another chamber 114, and a heat generating component 116 positioned in the chamber 112. At least one of the plural walls (e.g., wall 110) separates the chambers 112, 114. At least a portion of the wall 110 separating the chambers 112, 114 spans an area defined by a width (W) and a height (H). The wall portion has a surface area that is greater than a product of the width (W) and the height (H). The plural walls 102, 104, 106, 108, 110 define an airflow path adjacent to the wall portion for removing from the enclosure 100 heat generated by the heat generating component 116 and thermally conducted from the chamber 112 to the chamber 114 through the wall portion.

By having the surface area greater than the area (i.e., the product of the width (W) and the height (H)) of the wall portion between the chambers 112, 114, an area from which heat may be transferred from the chamber 112 to the chamber 114 is increased. Because the amount of heat transferred is based in part on the area of this heat transfer surface, more heat may be transferred between the chambers 112, 114.

The wall 110 separating the chambers 112, 114 may include a corrugated configuration. For example, as shown in FIG. 1, the wall 110 includes alternating ridges 120 and grooves 122 to increase its surface area. In other embodiments, the corrugated configuration may be alternating ridges or grooves, random ridges and/or grooves, periodic ridges and/or grooves, a single ridge, a single groove, etc. Additionally, the ridges and/or the grooves of the corrugated configuration may define triangle(s) (e.g., as shown in FIG. 1), a sinusoidal wave (e.g., as shown in FIG. 3a), a square wave (e.g., as shown in FIG. 3b), etc. In some cases, the corrugated configuration may extend continuously across the entire width of the wall 110 as shown in FIG. 1. Alternatively, the corrugated configuration may extend a distance less than the entire width and/or the wall 110 may include portions not including the corrugated configuration.

Additionally, although not shown in FIG. 1, any of the other walls 102, 104, 106, 108 may include the same or a different corrugated configuration of the wall 110. In some cases, this may further increase the amount of heat transferred from the chamber 112.

The multi-purpose enclosure 100 of FIG. 1 may employ passive methods to remove heat. For example, any one or all of the walls 102, 104, 106, 108 of the enclosure 100 may include vent(s) allowing air (indicated by arrows 118) to move through the enclosure 100 via the airflow path. In the particular example of FIG. 1, the wall 104 includes vents (not shown) for receiving air and the wall 108 includes vents (not shown) for exhausting air heated by heat thermally conducted between the chambers 112, 114 as explained above. By moving air through the enclosure 100, the temperature in the enclosure 100 may be substantially maintained at or about the temperature of the air.

In some examples, the walls 102, 104, 106, 108 may define an exterior of the enclosure 100. In such cases, the air moving through the vent(s) and the airflow path may be air external (e.g., ambient air) the enclosure 100 and thus the temperature in the enclosure 100 may be substantially maintained at or about the temperature of the external air. For example, if ambient air is passed through the enclosure 100, the temperature in the enclosure 100 may be maintained at about 46 degrees Celsius or another suitable temperature.

As shown in FIG. 1, the walls 104, 108 extend the entire length of the enclosure 100 and thus define portions of both the chamber 112 and the chamber 114. Alternatively, the enclosure 100 may include additional walls such that the chambers 112, 114 are defined by separate walls (except for the wall 110).

The heat generating component 116 of FIG. 1 is positioned within the chamber 112 such that a space is formed between the wall 110 and the heat generating component 116. Alternatively, the heat generating component 116 may be positioned against (e.g., connected to), integral with, etc. any one or more of the walls 104, 106, 108, 110. For example, and as further explained below, it may be preferable to have the heat generating component 116 connected to, integral with, etc. the wall 110 including the corrugated configuration as explained above.

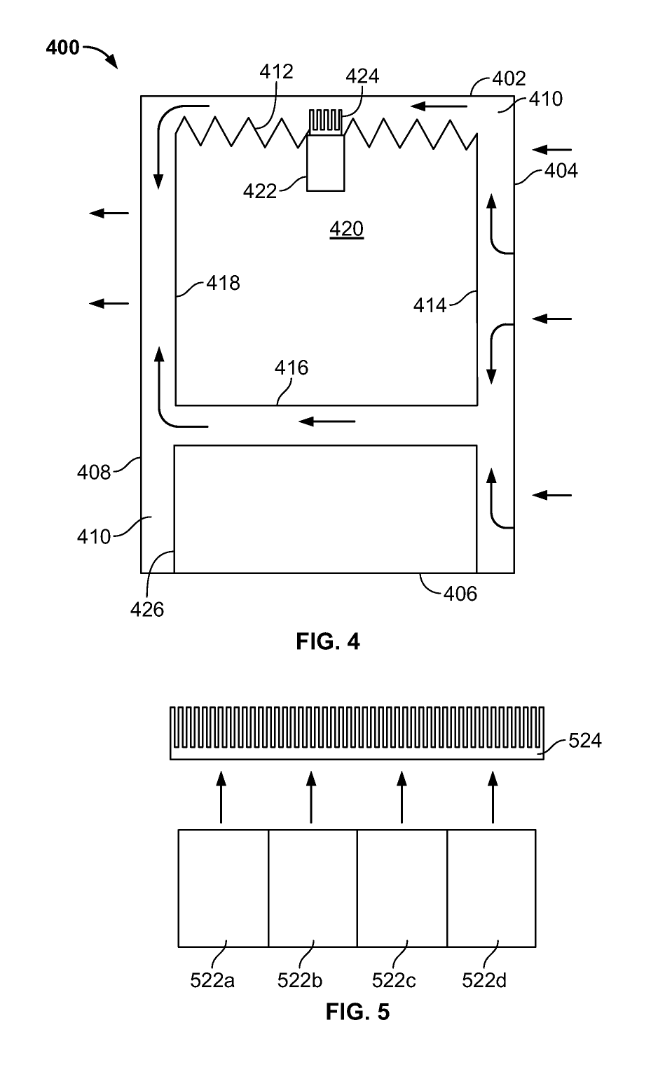

FIG. 4 illustrates another example multi-purpose enclosure 400 including walls 402, 404, 406, 408 defining a chamber 410, walls 412, 414, 416, 418 defining another chamber 420, and one heat generating component 422 positioned in the chamber 420. As shown in FIG. 4, the chamber 420 is positioned within the chamber 410. Thus, one of the chambers (e.g., the chamber 410) may include the other chamber (e.g., the chamber 420).

The walls 402, 404, 406, 408, 412, 414, 416, 418 define air flow paths between the chambers 410, 420 to allow air (e.g., ambient air) to move through the enclosure 400 as explained above with reference to FIG. 1. For example, one air flow path may be defined by the walls 402, 404, 408, 412, 414, 418 while another air flow path may be defined by the walls 404, 406, 408, 414, 416, 418.

In some cases, heat may penetrate the walls 402, 404, 406, 408 (e.g., solar penetration, etc.) and the walls 412, 414, 416, 418 (e.g., via conduction). By moving air through the enclosure 400 via the air flow paths, heat that may otherwise conduct into the chamber 420 may be removed from the enclosure 400.

The enclosure 400 may include one or more heat sinks thermally coupled to the heat generating component 422. For example, and as shown in FIG. 4, the enclosure 400 includes a heat sink 424 thermally coupled to the heat generating component 422. Thus, in this particular example, one heat sink is thermally coupled to one heat generating component.

The heat sink 424 may be thermally coupled to the heat generating component 422 in various ways. For example, the heat generating component 422 may include the heat sink 424, the heat sink 424 may be directly coupled to the heat generating component 422, etc. Thus, in such examples, the heat generating component 422 and heat sink 424 may be placed in a cutout of the wall 412.

In other examples, the heat sink 424 may be thermally coupled to the heat generating component 422 through one of the walls 412, 414, 416, 418 separating the chamber 410 and the chamber 420. For example, the heat generating component 422 and/or the heat sink 424 of FIG. 4 may be coupled to the wall 412 by, for example, adhesive including thermally conductive adhesive, mechanical fasteners, etc.

In the particular example of FIG. 4, the heat sink 424 and the heat generating component 422 are adjacent to the wall 412. However, the heat sink 424 and the heat generating component 422 may be adjacent to any one or more of the walls defining the chamber 420. Additionally, the enclosure 400 may include more than one heat sink and one heat generating component adjacent the same wall or different walls.

As shown in FIG. 4, the heat sink 424 is positioned in the airflow path at least partially defined by the wall 402 and the wall 412. By doing so, heat may be transferred from the heat generating component 422 to the airflow path through the heat sink 424. While FIG. 4 illustrates the entire heat sink 424 positioned in an airflow path, less than the entire heat sink 424 (e.g. a portion of the heat sink 424) may be positioned in an airflow path.

In some embodiments, the enclosure 400 may include one heat sink thermally coupled to two or more heat generating components. For example, FIG. 5 illustrates one heat sink 524 for thermally coupling to multiple heat generating components 522a, 522b, 522c, 522d. The heat sink 524 may be thermally coupled to the multiple heat generating components in a similar manner as explained above.

Referring back to FIG. 4, the enclosure 400 may include additional equipment positioned in the chamber 410. In the example of FIG. 4, the enclosure 400 includes equipment 426 positioned below the chamber 420. The equipment 426 may include electrical equipment including, for example, one or more batteries, converters, terminations, etc. In some examples, one or more walls may be utilized to partially and/or fully enclose the equipment 426, the equipment 426 may include walls, etc. These walls and/or the equipment 426 itself may define at least partially one of the air flow paths explained above and/or one or more additional air flow paths. Thus, heat generated by the equipment 426 may be removed by air moving through the enclosure as explained above. Therefore, the temperature of the equipment 426 may be maintained at or near the air temperature resulting in increased performance, life, etc. of the equipment 426.

In some example embodiments, an insufficient amount of heat is removed from the chamber 420 due to, for example, high temperatures, particular characteristics (e.g., material, performance, size, shape, etc.) of the chambers, the heat generating component, etc. In such cases, the enclosures disclosed herein may include one or more fans adjacent to the heat generating component(s) positioned in the chamber (as explained above). The fan(s) may be particular useful if the heat generating component(s) are positioned near a top portion of the chamber which would include a higher temperature than, for example, a bottom portion of the chamber.

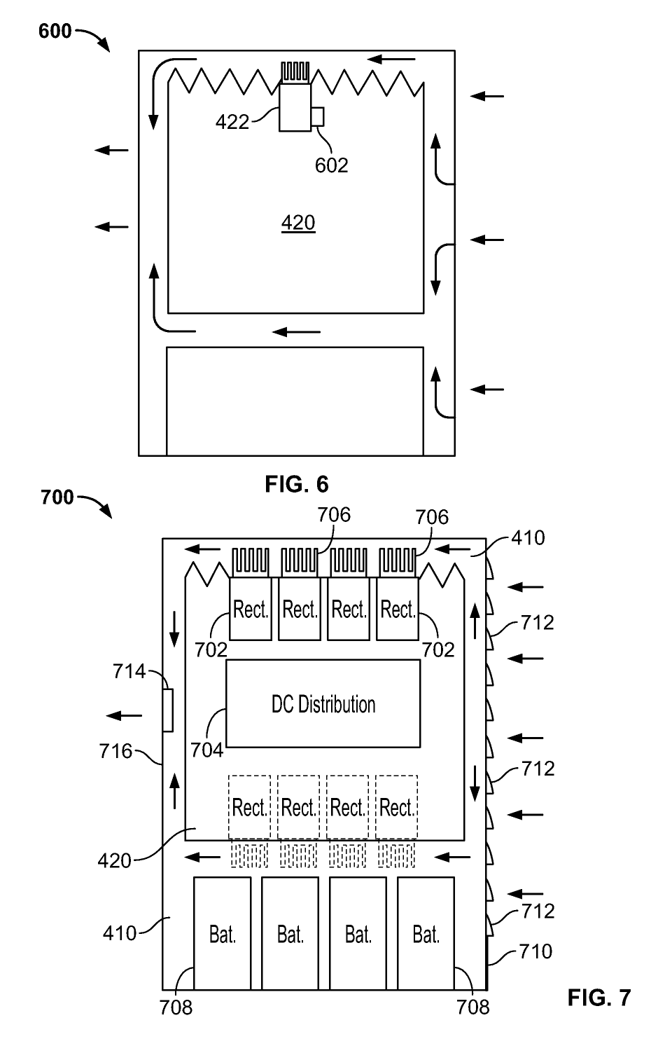

FIG. 6 illustrates an example multi-purpose enclosure 600 substantially similar to the multi-purpose enclosure 400 of FIG. 4. The enclosure 600 further includes a fan 602 adjacent to the heat generating component 422. The fan 602 may assist in cooling the heat generating component 422 by moving air across the heat generating component 422 and circulating cooler air near a bottom portion of the chamber 420 to a top portion of the chamber 420.

In the example of FIG. 6, the fan 602 is coupled to the heat generating component 422. The fan 602 may be coupled to the heat generating component 422 by, for example, adhesive including thermally conductive adhesive, mechanical fasteners, etc. Alternatively, the fan 602 may be coupled to one of the walls adjacent the generating component 422 in a similar fashion.

Additionally, in some examples, the enclosure 600 may include more than one heat generating component. In such cases, a fan may be adjacent (e.g., coupled) to each heat generating component, a fan may be adjacent (e.g., coupled) to one heat generating component but cool adjacent heat generating components, etc. The fan may be any suitable fan including, for example, a negative temperature coefficient (NTC) fan having integrated speed control and temperature sensing, a fan having external control and/or temperature sensing (e.g., a thermistor, etc.), etc.

FIG. 7 illustrates another example multi-purpose enclosure 700 similar to the enclosure 400 of FIG. 4. The enclosure 700 of FIG. 7, however, includes multiple heat generating components 702 and a DC distribution unit 704 positioned in the chamber 420, and multiple heat sinks 706 and multiple batteries 708 positioned in the chamber 410. The DC distribution unit 704 may include, for example, breakers, terminations, controllers, and/or other suitable DC distribution components.

As shown in FIG. 7, one heat sink 706 is thermally coupled to a respective heat generating component 702. The heat sinks 706 may be thermally coupled to the heat generating components 702 in a similar manner as described above. Additionally, at least a portion of each heat sink 706 is positioned in one or more air flow paths defined by walls of the chambers 410, 420 as explained above.

In the particular example of FIG. 7, the heat generating components 702 include rectifiers. However, one or more other heat generating components including, for example, converters, inverters, batteries, etc. may be employed in addition to or in alternative to the rectifiers.

As shown in FIG. 7, the rectifiers 702 are positioned in the upper portion of the chamber 420. Additionally or alternatively, rectifier(s) may be positioned in the lower portion of the chamber 420 as shown by rectifiers outlined in dashed lines. The position of the rectifiers may be, in part, dependent on gradient heat levels within the chamber 420. For example, the temperature near the lower portion of the chamber 420 may be about ten to about fifteen degrees Celsius lower than the temperature near the upper portion of the chamber 420.

Although FIG. 7 illustrates four rectifiers 702 positioned in the upper portion of the chamber 420 and four rectifiers (dashed lines) positioned in the lower portion of the chamber 420, more or less rectifiers may be employed if desired.

The rectifiers 702 of FIG. 7 are hardened rectifiers operable up to about seventy-five degrees Celsius. Alternatively, any one or all of the rectifiers 702 may be another suitable rectifier. In some embodiments, the rectifiers (and/or other heat generating component explained above) provide DC voltage in the range of about 12V to about 60V.

As shown in FIG. 7, the enclosure 700 includes four batteries 708 positioned near a bottom portion of the chamber 410 and, in particular, below the chamber 420 including the rectifiers 702. Alternatively, the batteries 708 may be positioned in another suitable position and/or the enclosure 700 may include more or less batteries.

The batteries 708 may define one or more air flow paths resulting in similar benefits as explained above with reference to the equipment 426 of FIG. 4. For example, air flow paths may be provided over, between, around, etc. the batteries 708.

In the example of FIG. 7, the batteries 708 provide backup DC power to a load in the event an electrical characteristic (e.g., an output voltage, an output current, etc.) of the rectifiers 702 drops below a defined threshold value (e.g., signifying a possible power outage, etc.). The batteries 708 may include one or more valve regulated lead acid (VRLA) batteries and/or other temperature sensitive batteries. Additionally, the rectifiers 702 and/or another suitable DC source may charge the batteries 708 when applicable.

In some embodiments, one or more of the walls defining the chambers 410, 420 may include a vent. For example, the enclosure 700 of FIG. 7 includes a wall 710 defining a portion of the chamber 410. The wall 710 includes vents 712 which allow air to move from outside the chamber 410 to inside the chamber 410 and through the air flow paths. Additionally, one or more other walls of the enclosure 700 (e.g., wall 716) may include vent(s) to allow air to move through the chamber 410.

As shown in FIG. 7, the vents 712 include projections extending from the wall 710 for substantially preventing water, debris, etc. from entering the chamber 410. Alternatively, the projections may not be needed in particular conditions and/or applications.

The vents 712 may include apertures extending through the wall 710, one or more louvers, etc. or any other suitable venting structure to allow air to move from outside the chamber 410 to inside the chamber 410.

Additionally, the enclosure 700 includes a fan 714 for moving air through the vents 712, the airflow paths, and between, for example, heat sink fins (if employed). For example, the fan 714 of FIG. 7 may be controlled to draw air into the chamber 410 and through the airflow paths via the vents 712. Additionally and alternatively, the fan 714 may be controlled to force air to exit the chamber 410 through the vents 712.

As shown in FIG. 7, the fan 714 is coupled to the wall 716 defining a portion of the chamber 410 and is positioned within the air flow paths. Thus, the fan 714 is positioned between the wall 716 defining the chamber 410 and the wall 418 defining the chamber 420. Alternatively, the fan 714 may be coupled to another suitable location including, for example, a different wall defining the chamber 410, a wall defining the chamber 420, an exterior side of the chamber 410, etc.

In the example of FIG. 7, the fan 714 includes a negative temperature coefficient (NTC) fan having integrated speed control. In this way, an electronic control unit (ECU) is not necessary to control the fan 714. As a result, costs associated with the fan 714 may be reduced.

Fan operation including, for example, the speed of the fan 714 may be based on a signal provided by a thermistor positioned in the chamber 420, external the chamber 410, etc. In such cases, the fan 714 may be operated, the speed may be adjusted, etc. when needed. Therefore, sensitive electronics within the chamber 420 may be protected from overheating, undesirable noise from the fan 714 may be heard when the fan 714 is on (e.g., when heat removal is needed), etc.

Alternatively, the fan 714 may include another suitable type of fan and/or be controlled in another suitable manner.

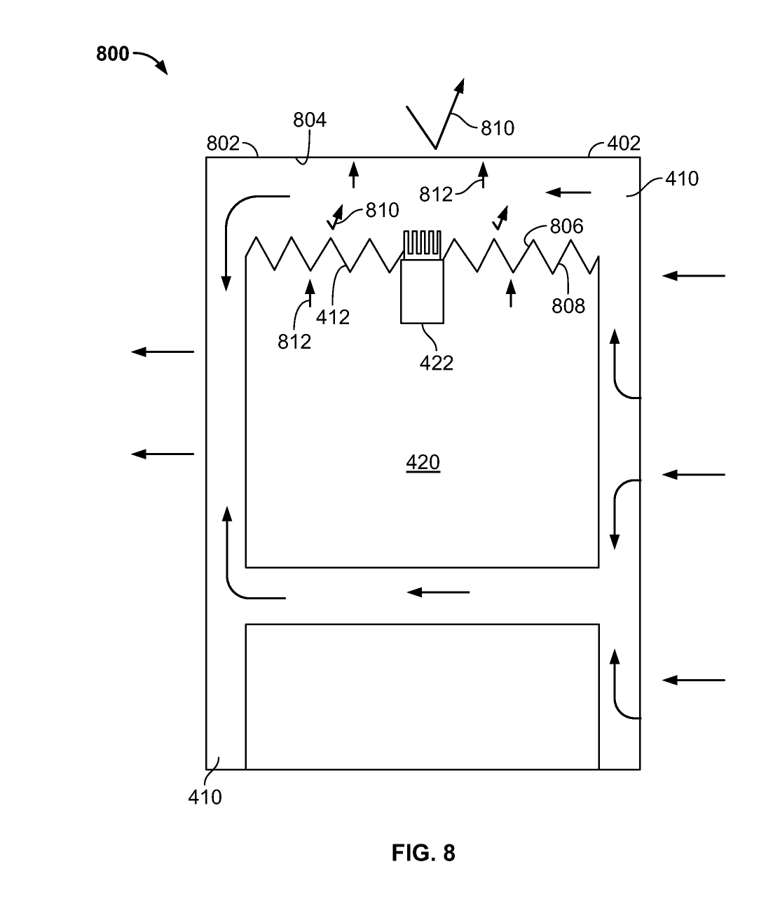

FIG. 8 illustrates another example multi-purpose enclosure 800 similar to the enclosure 400 of FIG. 4. The wall 402 defining a portion of the chambers 410 includes opposing sides 802, 804 while the wall 412 defining a portion of the chambers 420 includes opposing sides 806, 808. Each side 802, 804, 806, 808 of the walls 402, 412 has a reflection coefficient (e.g., a ratio of the radiation flux reflected by a surface to the incident radiation flux).

In the example of FIG. 8, the reflection coefficient of the side 802 is greater than the reflection coefficient of the side 804 while the reflection coefficient of the side 806 is greater than the reflection coefficient of the side 808. As a result, more radiation flux (e.g., heat from sunlight, etc.) is reflected from the sides 802, 806 compared to the sides 804, 808. Thus, because more radiation flux is reflected (as opposed to being absorbed), the temperature within the chambers may not substantially increase due to solar radiation, etc.

Additionally, the reflection coefficient of the sides 804, 808 may be at a sufficient level so that heat within the chambers 410, 420 may be absorbed and/or transmitted through the walls 402, 412 to assist in removing from the enclosure 800 heat generated by the heat generating component 422 as explained above. Therefore, one side of the wall (e.g., sides 802, 806) may be adapted to reflect more radiation flux (indicated by arrows 810) while the other side of the wall (e.g., sides 804, 808) may be adapted to absorb more radiation flux (indicated by arrows 812).

The reflection coefficient of a particular side of a wall may be based on a particular material of the wall, a material (e.g., a film, paint, etc.) placed on the wall, etc. For example, the wall may be aluminum (e.g., anodized aluminum) or another material that has a high reflection coefficient (e.g., about 0.8 to 0.95) compared to other materials.

In some embodiments, one or more sides of the wall(s) may be painted to make the reflection coefficient different for the opposing sides of the walls. For example, the side 802 of the wall 402 may be painted a color (e.g., a light color such as white, etc.) so that the reflection coefficient of the painted wall is higher than the opposing side 804. Additionally or alternatively, the side 804 of the wall 402 may be painted another color (e.g., a dark color such as black, etc.) so that the reflection coefficient of this painted wall is lower than the opposing side 802.

As shown in FIG. 8, the wall including different reflection coefficients is the wall 412 including the corrugated configurations as explained above and the wall 402 which may define an exterior surface of the enclosure 800. Additionally or alternatively, more or less walls may include different reflection coefficients if desired.

The multi-purpose enclosures disclosed herein may provide low cost solutions for cooling equipment therein while complying with applicable standards (e.g., Telcordia requirements, etc.). Additionally, the enclosures may be employed to provide power (e.g., DC power) to telecommunication equipment including, for example, wireline, wireless equipment and/or other suitable loads. Further, the enclosures including its components (e.g., chambers, rectifiers, heat sinks, batteries, etc.) may be modular to enable desired configurations, customer growth, etc.

The enclosures may be deployed indoors and/or outdoors. For example, the enclosures may be installed and operational in any various locations including, for example, on poles, walls (e.g., interior walls, exterior walls, etc. of a building, etc.), pads, etc. In some cases, the enclosures deployed indoors may not need environmentally sealed chambers (as further explained below), air filters, hardened electrical components (e.g., hardened rectifiers), etc.

Additionally, by employing the fans, heat sinks, vents, particular materials, etc. as disclosed herein, heat extraction from the enclosures may be improved. In turn, this may enable equipment (e.g., the DC distribution unit 320 of FIG. 7) within the chambers the ability to distribute more DC power.

Further, the enclosures may employ only passive methods (e.g., methods not consuming power) to cool equipment therein as explained above with respect to FIGS. 1, 4 and 8. In other embodiments, the enclosures may additionally employ semi-passive methods to cool equipment therein. For example, as explained above with respect to FIGS. 6 and 7, the equipment enclosures may include one or more power consuming fans to assist in circulating air throughout the enclosures.

The chambers disclosed herein may be any suitable material, size, shape, etc. and/or include any suitable finish. For example, materials, sizes, shapes, finishes, etc. of the chambers may be dependent on desired conduction and/or other heat removal characteristics. In some embodiments where one of the chambers is positioned in another chamber, the outer chamber may be aluminum having a thickness of about 0.075 inches to about 0.125 inches while the inner chamber may be aluminum having a thickness of about 0.09 inches.

The walls of the chambers may be formed of one continuous piece of material or formed of multiple pieces of material. For example, the walls may be formed of a sheet of aluminum, the walls (including portion of) may be defined by equipment housings in the chamber, etc.

Additionally, exterior walls of the enclosures can, but need not define the chambers. For example, in the embodiments where one of the chambers is positioned in another chamber, the walls of the outer chamber may be the exterior walls of the enclosure. Alternatively, one or more walls of the outer chamber may be a portion of the exterior walls of the enclosure, other chambers, walls, etc. may surround the two chambers, etc.

Further, the chambers including the heat generating component(s) may be environmentally sealed chambers. Thus, these chambers may include appropriate gaskets, seals, potting, etc. to ensure moisture, dirt, air, dust, etc. is prohibited from entering. As a result, performance of the components in the environmentally sealed chambers may be increased.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A multi-purpose enclosure for telecommunication applications, the enclosure comprising:
plural walls defining a first chamber and a second chamber;
a heat generating component positioned in the first chamber;
at least one of the plural walls separating the first chamber and the second chamber, at least a portion of the wall separating the first chamber and the second chamber spanning an area defined by a width and a height, the wall portion having a surface area that is greater than a product of said width and said height; and
the plural walls defining an airflow path adjacent to the wall portion for removing from the enclosure heat generated by the heat generating component and thermally conducted from the first chamber to the second chamber through the wall portion.

2. The enclosure of claim 1 further comprising a heat sink thermally coupled to the heat generating component.

3. The enclosure of claim 2 wherein at least a portion of the heat sink is positioned in the airflow path.

4. The enclosure of claim 2 wherein the heat sink is thermally coupled to the heat generating component through said at least one of the plural walls separating the first chamber and the second chamber.

5. The enclosure of claim 2 wherein the heat generating component is a first heat generating component, the multi-purpose enclosure further comprising a second heat generating component, wherein the heat sink is thermally coupled to the first heat generating component and the second first heat generating component.

6. The enclosure of claim 1 wherein the heat generating component includes at least one of a rectifier and a converter.

7. The enclosure of claim 1 wherein the first chamber is an environmentally sealed chamber.

8. The enclosure of claim 1 further comprising a fan adjacent to the heat generating component.

9. The enclosure of claim 1 wherein the first chamber is positioned in the second chamber.

10. The enclosure of claim 1 further comprising one or more batteries positioned in the second chamber.

11. The enclosure of claim 1 wherein at least one of the plural walls includes a vent and defines a portion of the second chamber.

12. The enclosure of claim 11 further comprising a fan for moving air through the vent and the airflow path.

13. The enclosure of claim 1 wherein the enclosure is deployed outdoors.

14. The enclosure of claim 1 wherein at least one of the plural walls includes a first side and a second side each having a reflection coefficient, and wherein the reflection coefficient of the first side is greater than the reflection coefficient of the second side.

15. The enclosure of claim 14 wherein the plural wall including the first side and the second side comprises said wall portion.

16. The enclosure of claim 14 wherein the plural wall including the first side and the second side defines an exterior surface of the enclosure.

17. The enclosure of claim 14 wherein the first side is a first color and the second side is a second color that is different than the first color.

18. The enclosure of claim 1 wherein the wall portion separating the first chamber and the second chamber includes at least one of one or more grooves and one or more ridges.
